(19) United States
(12) Patent Application Publication
(10) Pub. No.: US 2024/0371848 A1
(43) Pub. Date: Nov. 7, 2024

(54) DISPLAY SUBSTRATE, DISPLAY PANEL AND METHOD FOR PREPARING SAME

(71) Applicant: BOE Technology Group Co., Ltd., Beijing (CN)

(72) Inventors: Guangcai YUAN, Beijing (CN); Haixu LI, Beijing (CN)

(21) Appl. No.: 18/776,342

(22) Filed: Jul. 18, 2024

Related U.S. Application Data
(63) Continuation of application No. PCT/CN2023/084520, filed on Mar. 28, 2023.

(51) Int. Cl. H01L 25/16; H01L 33/00; H01L 33/52

(52) U.S. Cl. CPC H01L 25/167; H01L 33/005; H01L 33/52

(57) ABSTRACT

Provided is a display substrate. The display substrate includes: an adhesive layer disposed on a side of the substrate, wherein the adhesive layer includes a plurality of adhesive blocks arranged in an array; and a plurality of light-emitting diode groups disposed on a side, away from the substrate, of the adhesive layer, wherein each of the plurality of light-emitting diode groups includes at least one light-emitting diode, and the plurality of light-emitting diode groups are in one-to-one correspondence with the plurality of adhesive blocks; wherein the adhesive layer is an adhesive layer whose adhesion decreases under irradiation by a laser.

### CROSS-REFERENCE TO RELATED APPLICATION

This application is a continuation application of international application No. PCT/CN2023/084520, filed on Mar. 28, 2023, the content of which is herein incorporated by reference in its entirety.

### TECHNICAL FIELD

The present disclosure relates to the field of display technologies, and in particular, relates to a display substrate, a display panel, and a method for preparing the same.

### BACKGROUND

Typically, a micro light-emitting diode (Micro-LED) is a light-emitting diode with a micrometer size.

### SUMMARY

Embodiments of the present disclosure provide a display substrate, a display panel, and a method for preparing the same. The technical solutions are as follows.

According to some embodiments of the present disclosure, a display substrate is provided. The display substrate includes:
a substrate;
an adhesive layer disposed on a side of the substrate, wherein the adhesive layer includes a plurality of adhesive blocks arranged in an array; and
a plurality of light-emitting diode groups disposed on a side, away from the substrate, of the adhesive layer, wherein each of the plurality of light-emitting diode groups includes at least one light-emitting diode, and the plurality of light-emitting diode groups are in one-to-one correspondence with the plurality of adhesive blocks;
wherein the adhesive layer is an adhesive layer whose adhesion decreases under irradiation by a laser.

In some embodiments, an orthographic projection of a light-emitting region of the light-emitting diode in the light-emitting diode group on the substrate is within an orthographic projection of a corresponding adhesive block of the plurality of adhesive blocks on the substrate.

In some embodiments, the light-emitting diode has a first electrode and a second electrode, and the display substrate further includes: a first conductive pad electrically connected to the first electrode and a second conductive pad electrically connected to the second electrode, at least one of the first conductive pad and the second conductive pad being disposed on a side, away from the substrate, of the light-emitting diode.

In some embodiments, the first electrode and the second electrode of the light-emitting diode are both disposed on the side, away from the substrate, of the light-emitting diode, and a side, close to the substrate, of the light-emitting diode is adhered to a corresponding adhesive block of the plurality of adhesive blocks.

In some embodiments, the first electrode and the second electrode of the light-emitting diode are disposed on opposite sides of the light-emitting diode in a direction perpendicular to the substrate, and the first electrode is closer to the substrate relative to the second electrode; and
the display substrate further includes a transparent connection electrode disposed between the light-emitting diode and the adhesive block, wherein the transparent connection electrode is electrically connected to the first electrode of the light-emitting diode and the first conductive pad.

In some embodiments, a recess is formed in a side, away from the substrate, of the adhesive block, wherein the transparent connection electrode is disposed within the recess, and a thickness of the transparent connection electrode is greater than or equal to a depth of the recess; and a portion of the first electrode of the light-emitting diode is lapped to the transparent connection electrode, and the other portion of the first electrode of the light-emitting diode is affixed with the adhesive block.

In some embodiments, an orthographic projection of the recess on the substrate has at least one first side edge and at least one second side edge, wherein at least a portion of the first side edge is disposed within an orthographic projection of the light-emitting diode on the substrate, and the second side edge is disposed outside the orthographic projection of the light-emitting diode on the substrate.

In some embodiments, the orthographic projection of the light-emitting diode on the substrate has a third side edge adjacent to the first side edge, wherein a horizontal distance between the third side edge and the adjacent first side edge is greater than or equal to 2.5 microns.

In some embodiments, the light-emitting diode group includes at least two light-emitting diodes, wherein an orthographic projection of the light-emitting region of each of the light-emitting diodes in the light-emitting diode group on the substrate is within an orthographic projection of a corresponding adhesive block of the plurality of adhesive blocks on the substrate;
wherein in one of the light-emitting diode groups, the first electrodes of the respective light-emitting diodes are electrically connected to a same first lap pad, and the second electrodes of the respective light-emitting diodes are electrically connected to different second lap pads.

In some embodiments, the first electrode and the second electrode of the light-emitting diode are both disposed on the side, away from the substrate, of the light-emitting diode, the first lap pad includes a first pad body and at least two first connection electrodes, and each of the second lap pads includes a second pad body and a second connection electrode; wherein
an orthographic projection of the first pad body on the substrate and an orthographic projection of the second pad body on the substrate are both outside an orthographic projection of the light-emitting diode on the substrate;
in the first lap pad, the at least two first connection electrodes are in one-to-one correspondence with the at least two light-emitting diodes, one end of the first connection electrode is lapped to the first electrode of a corresponding light-emitting diode of the two light-emitting diodes, and the other end of the first connection electrode is electrically connected to the first pad body; and
in each of the second lap pads, one end of the second connection electrode is lapped to the second electrode of a corresponding light-emitting diode of the two light-emitting diodes, and the other end of the second connection electrode is electrically connected to the second pad body.

In some embodiments, the first electrode and the second electrode of the light-emitting diode are disposed on opposite sides of the light-emitting diode in a direction perpendicular to the substrate, and the display substrate further includes at least two transparent connection electrodes in one-to-one correspondence with the at least two light-emitting diodes, and an auxiliary connection electrode configured to connect each of the transparent connection electrodes;
wherein each of the transparent connection electrodes is lapped to the first electrode of a corresponding light-emitting diode of the two light-emitting diodes, and the auxiliary connection electrode is lapped to the first lap pad.

In some embodiments, at least two recesses in one-to-one correspondence with the at least two transparent connection electrodes, and an auxiliary recess configured to communicate with each of the at least two recesses are arranged in the adhesive block corresponding to one of the light-emitting diode groups, wherein each of the transparent connection electrodes is disposed in a corresponding recess, and the auxiliary connection electrode is disposed in the auxiliary recess.

In some embodiments, an orthographic projection of the auxiliary recess on the substrate is outside an orthographic projection of the light-emitting diode on the substrate, and an overlapping region is present between an orthographic projection of the first lap pad on the substrate and the orthographic projection of the auxiliary recess on the substrate; and
an orthographic projection of the second lap pad on the substrate is within the orthographic projection of the light-emitting diode on the substrate.

In some embodiments, the display substrate further includes: a plurality of insulating protective portions, wherein the plurality of insulating protective portions are in one-to-one correspondence with the plurality of adhesive blocks and in one-to-one correspondence with the plurality of light-emitting diode groups; wherein each of the plurality of insulating protective portions is configured to cover the light-emitting diode in a corresponding light-emitting diode group of the plurality of light-emitting diode groups, and an orthographic projection of the insulating protective portions on the substrate is within an orthographic projection of a corresponding adhesive block of the plurality of adhesive blocks on the substrate.

In some embodiments, the display substrate further includes a first lap pad and a second lap pad that are configured to be electrically connected to the light-emitting diode;
wherein the first lap pad and the second lap pad are both disposed on a side, away from the substrate, of the insulating protective portion; or, the second lap pad is disposed on the side, away from the substrate, of the insulating protective portion, and the first lap pad is disposed on a side, away from the substrate, of the adhesive block, and an orthographic projection of the first lap pad on the substrate is not coincident with the orthographic projection of the insulating protective portion on the substrate.

In some embodiments, the insulating protective portion includes an organic insulating layer and/or an inorganic insulating layer;
wherein the organic insulating layer covers each of the light-emitting diodes in a corresponding group of the light-emitting diode groups, and an angle between a side surface of the organic insulating layer and a side surface, close to the substrate, of the organic insulating layer is an acute angle.

In some embodiments, the insulating protective portion includes both the organic insulating layer and the inorganic insulating layer, the organic insulating layer being closer to the substrate relative to the inorganic insulating layer;
wherein the inorganic insulating layer is in contact with both the side surface of the organic insulating layer and a surface, away from the substrate, of the organic insulating layer.

In some embodiments, an orthographic projection of the organic insulating layer on the substrate is within an orthographic projection of the inorganic insulating layer on the substrate;
wherein the inorganic insulating layer is in direct contact with the adhesive block, and a region where the inorganic insulating layer is in contact with the adhesive block is in a closed ring shape and surrounds the organic insulating layer.

In some embodiments, the light-emitting diode is a mini light-emitting diode or a micro light-emitting diode.

According to some embodiments of the present disclosure, a display panel is provided. The display panel includes a display substrate and a driving backplane, the display substrate is the display substrate described above;
wherein the driving backplane is disposed on a side, away from a substrate, of a plurality of light-emitting diodes in the display substrate, and the driving backplane is electrically connected to the plurality of light-emitting diodes.

According to some embodiments of the present disclosure, a method for preparing a display panel is provided. The method includes:
forming an adhesive layer on a side of a substrate, wherein the adhesive layer includes a plurality of adhesive blocks arranged in an array, and the adhesive layer is an adhesive layer whose adhesion decreases under irradiation by a laser;
acquiring a display substrate by forming a plurality of light-emitting diode groups on a side, away from the substrate, of the adhesive layer, wherein the light-emitting diode groups include at least one light-emitting diode, and the plurality of light-emitting diode groups are in one-to-one correspondence with the plurality of adhesive blocks; and
connecting a driving backplane to a side of the display substrate, wherein the driving backplane is disposed on a side, away from the substrate, of the plurality of light-emitting diodes in the display substrate, and the driving backplane is electrically connected to each of the light-emitting diodes.

In some embodiments, prior to connecting the driving backplane to the side of the display substrate, the method further includes:
testing each of the light-emitting diodes in the display substrate by test equipment;
in a case where a particular light-emitting diode of the light-emitting diodes is tested to be defective, irradiating, using laser equipment, laser light to the adhesive block corresponding to the light-emitting diode which is defective, such that the light-emitting diode which is defective is separated from the substrate and a region to be repaired is formed on the substrate; and
re-forming the adhesive block and the light-emitting diode within the region to be repaired; or
in a case where each of the light-emitting diodes is tested to be normal, performing the step of connecting the driving backplane to the side of the display substrate.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic diagram of a film layer structure of a display substrate according to some embodiments of the present disclosure;

FIG. 2 is a schematic diagram of a film layer structure of the display substrate illustrated in FIG. 1 along a line A-A′;

FIG. 3 is a schematic diagram of a film layer structure of another display substrate according to some embodiments of the present disclosure;

FIG. 4 is a top view of the display substrate illustrated in FIG. 3;

FIG. 5 is a schematic diagram of a film layer structure of yet another display substrate according to some embodiments of the present disclosure;

FIG. 6 is a top view of the light-emitting diode illustrated in FIG. 5;

FIG. 7 is a schematic diagram of a film layer structure of yet another display substrate according to some embodiments of the present disclosure;

FIG. 8 is a schematic diagram of a film layer structure of a display substrate according to some embodiments of the present disclosure;

FIG. 9 is a top view of the display substrate illustrated in FIG. 8;

FIG. 10 is a schematic diagram of a film layer structure of another display substrate according to some embodiments of the present disclosure;

FIG. 11 is a top view of the display substrate illustrated in FIG. 10;

FIG. 12 is a schematic diagram of a film layer structure of yet another display substrate according to some embodiments of the present disclosure;

FIG. 13 is a schematic diagram of a film layer structure of a display substrate according to some embodiments of the present disclosure;

FIG. 14 is a schematic diagram of a film layer structure of a display panel according to some embodiments of the present disclosure;

FIG. 15 is a flowchart of a method for preparing a display panel according to some embodiments of the present disclosure; and

FIG. 16 is a flowchart of a method for testing a display substrate according to some embodiments of the present disclosure.

### DETAILED DESCRIPTION

The present disclosure is described in further detail with reference to the accompanying drawings, to clearly present the objects, technical solutions, and advantages of the present disclosure.

Because of their small size, micro LEDs can be used as pixels in display panels, and display panels prepared by using micro LEDs are referred to as micro-LED display panels. Compared with an organic light-emitting diode (OLED) display panel, the micro LED display panel has better service life and viewing angle, and thus the micro LED display technology has become a research focus in the field of display technology.

However, some micro-LEDs in the micro-LED display panel have defects of poor luminescence, which leads to a poor display effect of the micro-LED display panel.

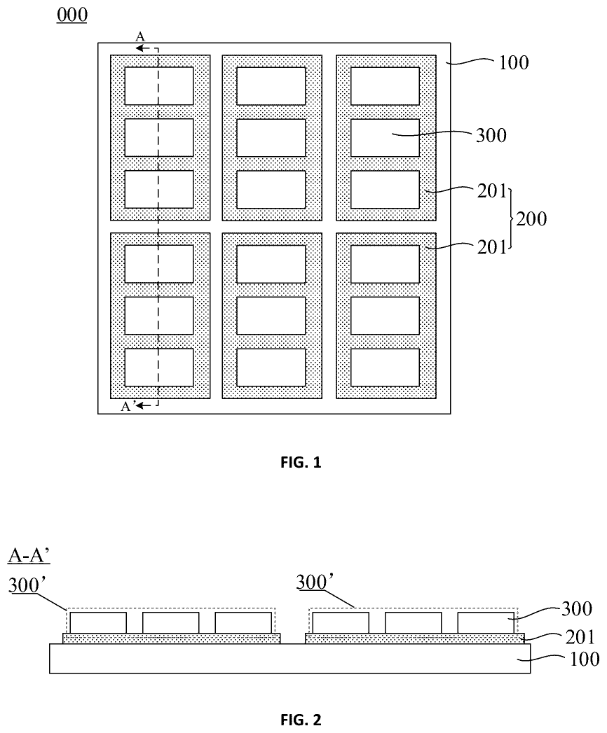

FIG. 1 is a schematic diagram of a film layer structure of a display substrate according to some embodiments of the present disclosure. FIG. 2 is a schematic diagram of a film layer structure of the display substrate illustrated in FIG. 1 along a line A-A′. Referring to FIGS. 1 and 2, the display substrate 000 includes a substrate 100, an adhesive layer 200, and a plurality of light-emitting diodes 300.

The adhesive layer 200 in the display substrate 000 is disposed on a side of the substrate 100, and the adhesive layer 200 includes a plurality of adhesive blocks 201 arranged in an array.

The plurality of light-emitting diodes 300 in the display substrate 000 are all disposed on a side, away from the substrate 100, of the adhesive layer 200, and the plurality of light-emitting diodes 300 in the display substrate 000 are organized into a plurality of light-emitting diode groups 300′. Each of the light-emitting diode groups 300′ includes at least one light-emitting. Here, the plurality of light-emitting diode groups 300′ are in one-to-one correspondence with the plurality of adhesive blocks. That is, each adhesive block 201 in the display substrate 000 corresponds to one light-emitting diode 300 or corresponds to at least two light-emitting diodes 300, which is not limited herein. It should be noted that each light-emitting diode 300 in the display substrate 000 is adhered to the substrate 100 by the corresponding adhesive block 201.

It should be noted that the light-emitting diode 300 in the display substrate 000 is a normal-sized LED, a mini light-emitting diode (mini-LED), or a micro-LED.

In some embodiments of the present disclosure, the adhesive layer 200 in the display substrate 000 is an adhesive layer whose adhesion decreases under the irradiation by a laser. In this case, when each light-emitting diode 300 in the display substrate 000 is adhered to the substrate 100 by a corresponding adhesive block 201, where the light emitted from a light-emitting diode 300 is found to be defective in the process of inspecting these light-emitting diodes 300, laser light is irradiated to the adhesive block 201 corresponding to this defective light-emitting diode 300, such that the adhesion between the adhesive block 201 and the substrate 100 is reduced, and thus the adhesive block 201 is separated from the substrate. In this way, this defective light-emitting diode 300 is detached from the substrate 100. Here, after this adhesive block 201 is detached from the substrate 100, a region to be repaired is formed on the substrate 100, which is used to adhere the defective light-emitting diode 300. Subsequently, a new adhesive block 201 is provided in the region to be repaired, and a new light-emitting diode 300 is adhered to the adhesive block 201. Accordingly, by providing the adhesive layer 200 on the substrate 101 whose adhesion is reduced by laser irradiation and adhering the light-emitting diode 300 to the adhesive layer 200, the defective light-emitting diode in the display substrate 000 is repaired, such that each of the light-emitting diodes in the display substrate 000 is capable of emitting light normally, and after the display substrate 000 is subsequently assembled to the display panel, the display effect of the display panel is ensured to be good.

In summary, some embodiments of the present disclosure provide a display substrate, including: the substrate, the adhesive layer, and the plurality of light-emitting diodes. The adhesive layer includes the plurality of adhesive blocks corresponding to the plurality of light-emitting diodes. The adhesive layer is an adhesive layer whose adhesion decreases under the irradiation by a laser. In the case where each of the light-emitting diodes in the display substrate is adhered to the substrate by the corresponding adhesive block, if the light emitted from a light-emitting diode is found to be defective in the testing process of the light-emitting diodes, laser light is irradiated to the adhesive block corresponding to this light-emitting diode, such that the adhesion between the adhesive block and the substrate is reduced, and thus the adhesive block is separated from the substrate. In this way, the defective light-emitting diode is detached from the substrate, such that a new adhesive block is subsequently provided and a new light-emitting diode is adhered to the new adhesive block. Therefore, by providing the adhesive layer on the substrate whose adhesion is reduced under laser irradiation, and adhering the light-emitting diode on the adhesive layer, the light-emitting diode that is defective in the display substrate can be repaired, such that each of the light-emitting diodes in the display substrate is capable of emitting light normally. After the display substrate is subsequently assembled into the display panel, the display effect of the display panel is ensured to be good.

It should be noted that the light-emitting diode 300 in the display substrate 000 has a light-emitting region. Exemplarily, the light-emitting region of the light-emitting diode 300 is usually provided with a quantum well layer, and an N-type semiconductor layer and a P-type semiconductor layer are disposed on both sides of the quantum well layer. After supplying power to the light-emitting diode 300, the N-type semiconductor layer in the light-emitting diode 300 injects electrons into the quantum well layer, and the P-type semiconductor layer injects holes into the quantum well layer. After the holes and the electrons are compounded into excitons in the quantum well layer, the excitons recombine to emit light in the quantum well layer, such that the quantum well layer is capable of emitting light. It should be noted that the light-emitting diode 300 is capable of emitting light to a side close the substrate 100.

In some embodiments of the present disclosure, an orthographic projection of the light-emitting region of the light-emitting diode group 300 of the light-emitting diode group 300′ on the substrate 100 is within an orthographic projection of the corresponding adhesive block 201 on the substrate 100. In this case, the adhesive block 201 is capable of not only adhering the corresponding light-emitting diode 300 to the substrate 100, but also ensuring that the light emitted from the light-emitting diode 300 is directed to the substrate 100 after passing through the adhesive block 201, such that the light emitted from the light-emitting diode 300 is ensured to be uniform.

In some embodiments, the orthographic projection of the light-emitting diode group 300 of the light-emitting diode group 300′ on the substrate 100 is completely within the orthographic projection of the corresponding adhesive blocks 201 on the substrate 100. In this case, if an adhesive block 201 is separated from the substrate 100 under the irradiation by a laser, it is ensured that the light-emitting diodes 300 corresponding to this adhesive block 201 can be completely detached from the substrate 100.

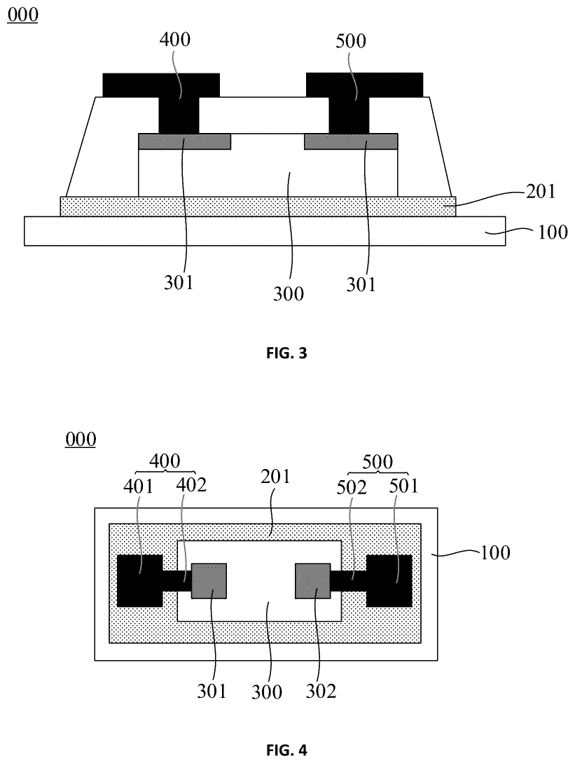

FIG. 3 is a schematic diagram of a film layer structure of another display substrate according to some embodiments of the present disclosure. In the present disclosure, the light-emitting diode 300 in the display substrate 000 has a first electrode 301 and a second electrode 302. The first electrode 301 and the second electrode 302 in the light-emitting diode 300 belong to an electrode structure within the light-emitting diode 300. That is, after preparing the light-emitting diode 300, the light-emitting diode 300 has the first electrode 301 and the second electrode 302 therein. In the interior of the light-emitting diode 300, one of the first electrode 301 and the second electrode 302 is electrically connected to the N-type semiconductor layer and the other is electrically connected to the P-type semiconductor layer. For example, one of the first electrode 301 is an N electrode electrically connected to the N-type semiconductor layer, and the other is a P electrode electrically connected to the P-type semiconductor layer.

Optionally, the display substrate 000 further includes a first conductive pad 400 electrically connected to the first electrode 301 of the light-emitting diode 300, and a second conductive pad 500 electrically connected to the second electrode 302 of the light-emitting diode 300. Here, at least one of the first conductive pad 400 and the second conductive pad 500 is disposed on a side, away from the substrate 100, of the light-emitting diode 300.

It should be noted that the first electrode 301 and the second electrode 302 in the light-emitting diode 300 belong to the electrode structure within the light-emitting diode 300, and the first conductive pad 400 and the second conductive pad 500 belong to the display substrate 000. Thus, the first electrode 301 is not identical to the first conductive pad 400, and the second electrode 302 is not identical to the second conductive pad 500. Here, after forming the light-emitting diode 300 on the side, away from the substrate 100, of the adhesive layer 200 by connection, the first conductive pad 400 electrically connected to the first electrode 301 of the light-emitting diode 300 and the second conductive pad 500 electrically connected to the second electrode 302 of the light-emitting diode 300 are then separately formed.

In the present disclosure, as shown in FIG. 3, both the first conductive pad 400 and the second conductive pad 500 are disposed on the side, away from the substrate 100, of the light-emitting diode 300. In this way, when a light-emitting diode 300 in the substrate 000 needs to be tested, two probes in the test equipment are allowed to respectively abut the first conductive pad 400 and the second conductive pad 500 to which this light-emitting diode 300 is connected, such that the test equipment is electrically connected to this light-emitting diode 300. Then after the test equipment transmits a test signal to this light-emitting diode 300, the test equipment controls the light-emitting diode 300 to light up. Here, un a case where the light-emitting diode 300 is lit normally, and the luminance of the light emitted by the light-emitting diode 300 is within a specified luminance range, the light-emitting diode 300 belongs to a normal light-emitting diode; and in a case where the light-emitting diode 300 cannot be lit, or in a case where the light-emitting diode 300 is lit, but the luminance of the light emitted by the light-emitting diode 300 is low, the light-emitting diode 300 belongs to a defective light-emitting diode, and the display substrate 000 needs to be subsequently repaired accordingly.

In addition, in the case where both the first conductive pad 400 and the second conductive pad 500 are disposed on the side, away from the substrate 100, of the light-emitting diode 300, the subsequent connection process between a driving backplane and the display substrate 000 is simplified. Exemplarily, the driving backplane is disposed on the side, away from the substrate 100, of the light-emitting diode 300, such that the driving backplane 300 is directly electrically connected to the light-emitting diode 300 by being welded to the first conductive pad 400 and the second conductive pad 500, and thus the driving backplane is capable of driving the corresponding light-emitting diode 300 to emit light by the first conductive pad 400 and the second conductive pad.

FIG. 4 is a top view of the display substrate illustrated in FIG. 3. In some embodiments of the present disclosure, as shown in FIG. 4, each of orthographic projections of the first conductive pad 400 and the second conductive pad 500 in the display substrate 000 on the substrate 100 is disposed within an orthographic projection of the corresponding adhesive block 201 on the substrate 100. In the present disclosure, the orthographic projection of at least one of the first conductive pad 400 and the second conductive pad 500 on the substrate 100 is disposed within the orthographic projection of the corresponding light-emitting diode 300 on the substrate 100. In some embodiments, the orthographic projection of each of the first conductive pad 400 and the second conductive pad 500 on the substrate 100 is outside the orthographic projection of the corresponding light-emitting diode 300 on the substrate 100, which is not limited herein.

Optionally, the orthographic projection of the light-emitting diode 300 on the substrate 100 is typically rectangular, and accordingly, the orthographic projection of the adhesive block 201 on the substrate 100 corresponding to this light-emitting diode 300 is also rectangular.

Here, during the preparation process of the display substrate 000, the adhesive glue block 201 in the display substrate 000 usually needs to be acquired by using a mask plate to perform a patterning process. For example, a whole layer of the adhesive layer is formed first on the substrate 100, then the adhesive layer is exposed by using a mask plate, and then the exposed adhesive layer is developed, such that a patterned adhesive layer 200 is acquired, which contains a plurality of adhesive blocks 201. The light-emitting diode 300 in the display substrate 000 usually needs to be acquired by using a transfer process. For example, the light-emitting diode 300 is formed on a sapphire substrate first, and then the light-emitting diode 300 on the sapphire substrate is transferred to the side, away from the substrate 100, of the adhesive layer 200 by a transfer process, such that the light-emitting diode 300 is adhered to the substrate 100 by the corresponding adhesive block 201 in the adhesive layer 200.

It should be noted that due to the existence of an exposure error in the exposure process of the adhesive layer arranged in a whole layer by using a mask plate, and the existence of a transfer error in the transfer process of the light-emitting diode 300, to ensure that the orthographic projection of the light-emitting diode 300 in the display substrate 000 on the substrate 100 is completely within the orthographic projection of the corresponding adhesive block 201 on the substrate 100, it is necessary to allow a certain distance between a boundary of the light-emitting diode 300 and a boundary of the adhesive block 201 during the design stage, and this distance needs to be greater than or equal to the sum of the exposure accuracy in using the mask plate to perform the exposure process and the transfer accuracy of transferring the light-emitting diode 300. In this way, even if there is a certain exposure error when using the mask plate for the exposure process and there is a certain transfer error during the transfer of the light-emitting diode, the orthographic projection of the light-emitting diode 300 on the substrate 100 is completely within the orthographic projection of the corresponding adhesive block 201 on the substrate 100 after the light-emitting diode 300 has been transferred to the adhesive block 201.

It should be noted that in a case where the orthographic projection of the conductive pad (which is the first conductive pad 400 or the second conductive pad 500) on the substrate 100 is outside the orthographic projection of the corresponding light-emitting diode 300 on the substrate 100, a distance needs to be present between a boundary, away from the light-emitting diode 300, of this conductive pad and a boundary of the adhesive block 201 at the design stage, and this distance also needs to be greater than or equal to the sum of the exposure accuracy when the mask plate is used for the exposure process and the transfer accuracy of transferring the light-emitting diode 300.

In some embodiments of the present disclosure, there are various types of light-emitting diodes 300 within the display substrate 000. For example, the light-emitting diode 300 is a flip-chip type light-emitting diode, and for example, the light-emitting diode 300 is a vertical-type light-emitting diode. To this end, some embodiments of the present disclosure give the description using the following two optional implementations as an example.

In a first optional implementation, as shown in FIG. 3, in a case where the light-emitting diode 300 is a flip-chip type light-emitting diode, both the first electrode 301 and the second electrode 302 of the light-emitting diode 300 are disposed on a side, away from the substrate 100, of the light-emitting diode 300, and a side, close to the substrate 100, of the light-emitting diode 300 is affixed to the corresponding adhesive block 200.

In this case, the first conductive pad 400 disposed on the side, away from the substrate 100, of the light-emitting diode 300 is lapped directly to the first electrode 301 of the light-emitting diode 300, and the second conductive pad 200 disposed on the side, away from the substrate 100, of the light-emitting diode 300 is also lapped directly to the second electrode 302 of the light-emitting diode 300.

It should be noted that, as shown in FIG. 4, the first conductive pad 400 includes a first pad body 401 and a first connection electrode 402, and the second conductive pad 500 includes a second pad body 501 and a second connection electrode 502. Here, one end of the first connection electrode 402 is electrically connected to the first pad body 401, and the other end is electrically connected to the first electrode 301 of the light-emitting diode 300; and one end of the second connection electrode 502 is electrically connected to the second pad body 501, and the other end is electrically connected to the second electrode 302 of the light-emitting diode 300. In this case, when the light-emitting diode 300 is a micro LED, due to the small size of the micro LED, to ensure that the first conductive pad 400 and the second conductive pad 500 are both normally electrically connected to the light-emitting diode 300, the orthographic projections of the first pad body 401 and the second pad body 501 on the substrate 100 are both outside the orthographic projection of the light-emitting diode 300 on the substrate 100, and the first pad body 401 and the second pad body 501 are disposed on opposite sides of the light-emitting diode 300. In this way, it is ensured that the distance between the first pad body 401 and the second pad body 501 is large, and thus there is no short circuit between the two.

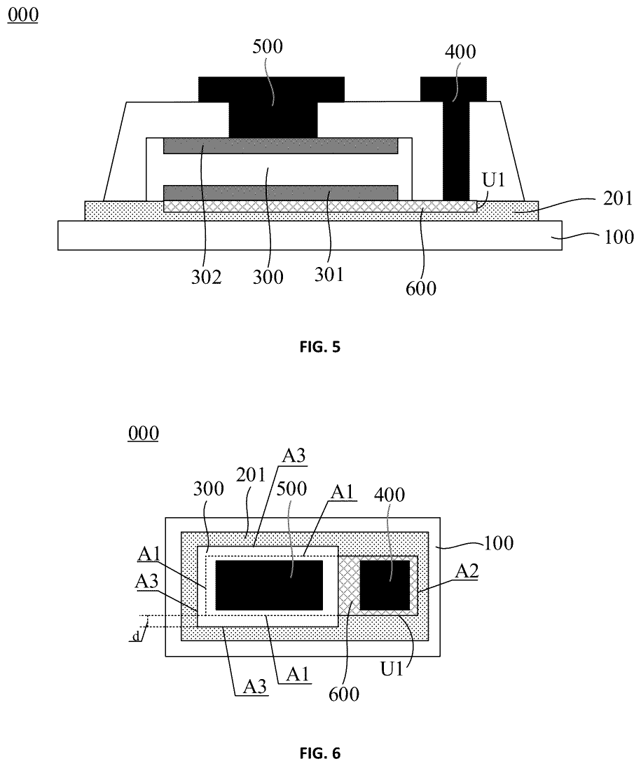

In a second optional implementation, as shown in FIG. 5, which is a schematic diagram of a film layer structure of yet another display substrate according to some embodiments of the present disclosure, in a case where the light-emitting diode 300 is a vertical-type light-emitting diode, the first electrode 301 and the second electrode 302 of the light-emitting diode 300 are disposed on opposite sides of the light-emitting diode 300 in a direction perpendicular to the substrate 100, and in the light-emitting diode 300, the first electrode 301 is closer to the substrate 100 relative to the second electrode 302.

Here, the display substrate 000 further includes a transparent connection electrode 600 disposed between the light-emitting diode 300 and the adhesive block 201. The transparent connection electrode 600 is electrically connected to the first electrode 301 of the light-emitting diode 300 and the first conductive pad 400.

In this case, the first conductive pad 400 disposed on the side, away from the substrate 100, of the light-emitting diode 300 is lapped to the first electrode 301 of the light-emitting diode 300 by the transparent connection electrode 600, and the second conductive pad 200 disposed on the side, away from the substrate 100, of the light-emitting diode 300 is also lapped directly to the second electrode 302 of the light-emitting diode 300. In addition, the light-emitting diode 300 is capable of emitting light along a direction toward the substrate 100, and therefore, in a case where the transparent connection electrode 600 is provided between the light-emitting diode 300 and the adhesive block 201, the transparent connection electrode 600 not only connects the first electrode of the light-emitting diode 300 to the first conductive pad 400, but also ensures that the light emitted by the light-emitting diode 300 is not shielded by itself, such that the light-emitting diode 300 is capable of emitting light normally.

FIG. 6 is a top view of the light-emitting diode illustrated in FIG. 5. It should be noted that as shown in FIG. 6, the orthographic projection of the first conductive pad 400 on the substrate 100 is outside the orthographic projection of the light-emitting diode 300 on the substrate 100, and the orthographic projection of the second conductive pad 500 on the substrate 100 is within the orthographic projection of the light-emitting diode 300 on the substrate 100. In this case, even if the light-emitting diode 300 is a mini LED with a small size, by extending a length of the transparent connection electrode 600, a large distance between the first conductive pad 400 and the second conductive pad 500 is ensured. In this way, even if the orthographic projection of the second conductive pad 500 on the substrate 100 is within the orthographic projection of the light-emitting diode 300 on the substrate 100, it is ensured that there is no short-circuit between the first conductive pad 400 and the second conductive pad 500.

Optionally, as shown in FIG. 5, a recess U1 is formed in a side, away from the substrate 100, of the adhesive block 201 in the display substrate 000. The transparent connection electrode 600 in the display substrate 000 is within the recess U1. Here, a thickness of the transparent connection electrode 600 is greater than or equal to a depth of the recess U1. Exemplarily, in a case where the thickness of the transparent connection electrode 600 is equal to the depth of the recess U1, a side, away from the substrate 100, of the transparent connection electrode 600 is flush with a portion of a side, away from the substrate 100, of the adhesive block 201 except for a portion where the recess U1 is formed. In this case, a portion of the first electrode 301 of the light-emitting diode 300 is lapped to the transparent connection electrode 600, and another portion is affixed with the adhesive block 201. In this way, a region, affixed to the adhesive block 201, is present in the light-emitting diode 300, such that the light-emitting diode 300 is securely arranged on the adhesive block 201.

In some embodiments of the present disclosure, as shown in FIG. 6, to make a portion adhered to the adhesive block 201 present in the first electrode 301 of the light-emitting diode 300, and to make the transparent connection electrodes 600 disposed inside the recess U1 achieve the electrical connection between the first electrode 301 of the light-emitting diode 300 and the first conductive pad 400, it is necessary to allow a portion of a boundary of an orthographic projection of the recess U1 on the substrate 100 to be within the orthographic projection of the light-emitting diode 300 on the substrate 100, and another portion of the boundary to be outside the orthographic projection of the light-emitting diode 300 on the substrate 100. Exemplarily, the orthographic projection of the recess U1 within the adhesive block 201 on the substrate 100 has at least one first side edge A1 and at least one second side edge A2. At least a portion of the first side edge A1 is within the orthographic projection of the light-emitting diode 300 on the substrate 100, and the second side edge A2 is outside the orthographic projection of the light-emitting diode 300 on the substrate 100.

It should be noted that in a case where the shape of the orthographic projection of the light-emitting diode 100 on the substrate 100 is rectangular, the shape of the orthographic projection of the recess U1 in the adhesive block 201 on the substrate 100 is also rectangular, and a length of the recess U1 is greater than a length of the light-emitting diode 100. In this case, the orthographic projection of the recess on the substrate has three first side edges A1 and one second side edge A2. Here, one first side edge, opposite to the second side edge A2, of the three first side edges A1 is completely within the orthographic projection of the light-emitting diode 300 on the substrate 100, whereas a portion of other two of the three first side edges A1 is within the orthographic projection of the light-emitting diode 300 on the substrate 100.

In some embodiments of the present disclosure, the orthographic projection of the light-emitting diode 300 on the substrate 100 has a third side edge A3 adjacent to the first side edge A1, and a horizontal distance d between the third side edge A3 and the adjacent first side edge A1 is greater than or equal to 2.5 microns. In this way, the adhesive block 201 is ensured to have a high adhesive capacity to the light-emitting diode 300, such that the light-emitting diode 300 is more firmly arranged within the display substrate 000.

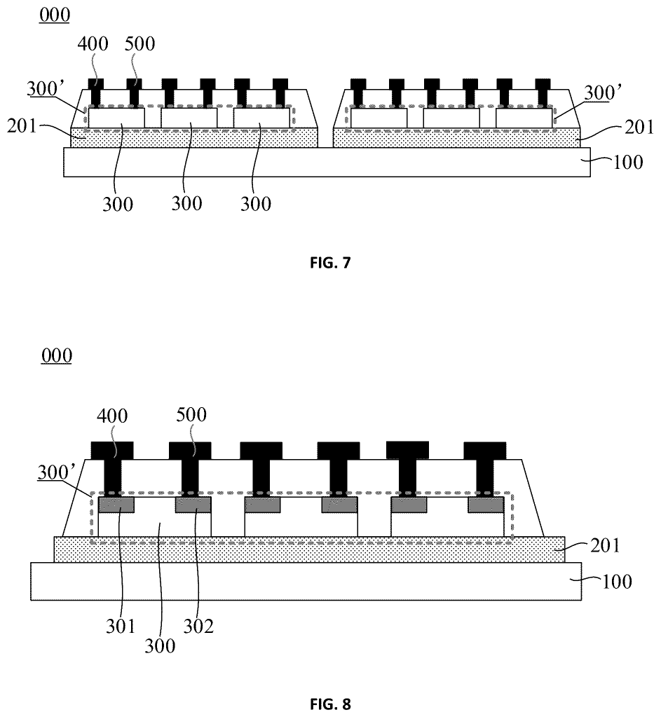

FIG. 7 is a schematic diagram of a film layer structure of yet another display substrate according to some embodiments of the present disclosure. Optionally, as shown in FIG. 7, each light-emitting diode group 300′ in the display substrate 000 includes at least two light-emitting diodes 300. Exemplarily, each light-emitting diode group 300′ includes three light-emitting diodes 300, and the three light-emitting diodes 300 are, respectively, a light-emitting diode for emitting red light, a light-emitting diode for emitting green light, and a light-emitting diode for emitting blue light. In this way, a region corresponding to one light-emitting diode group 300′ in the display substrate 000 is a region where one pixel is disposed.

Here, the orthographic projection of the light-emitting region of each light-emitting diode 300 in the light-emitting diode group 300′ on the substrate 100 is within the orthographic projection of the corresponding adhesive block 201 on the substrate 100. For example, the orthographic projection of each of the light-emitting diodes 300 in the light-emitting diode group 300′ on the substrate 100 is within the orthographic projection of the corresponding adhesive block 201 on the substrate 100.

In the present disclosure, to simplify the structure of the display substrate 000, in one light-emitting diode group 300′, the first electrodes 301 of the respective light-emitting diode 300 are electrically connected to the same first lap pad 400, and the second electrodes 302 of the respective light-emitting diode 300 are electrically connected to different second lap pads 500. Exemplarily, the second electrodes 302 of at least two light-emitting diodes 300 in the light-emitting diode group 300′ are electrically connected to at least two different second lap pads 500, respectively. That is, the respective light-emitting diodes 300 in each light-emitting diode group 300′ in the display substrate 000 share one first lap pad 400, while the second lap pads 500 are not shared. In this way, after different second lap pads 500 are accessed with different signals, different light-emitting diodes 300 in the same light-emitting diode group 300 are capable of emitting light of luminance.

It should be noted that since the light-emitting diode 300 is either a flip-chip type light-emitting diode or a vertical-type light-emitting diode, the embodiments of the present disclosure give the description using the following two cases as an example.

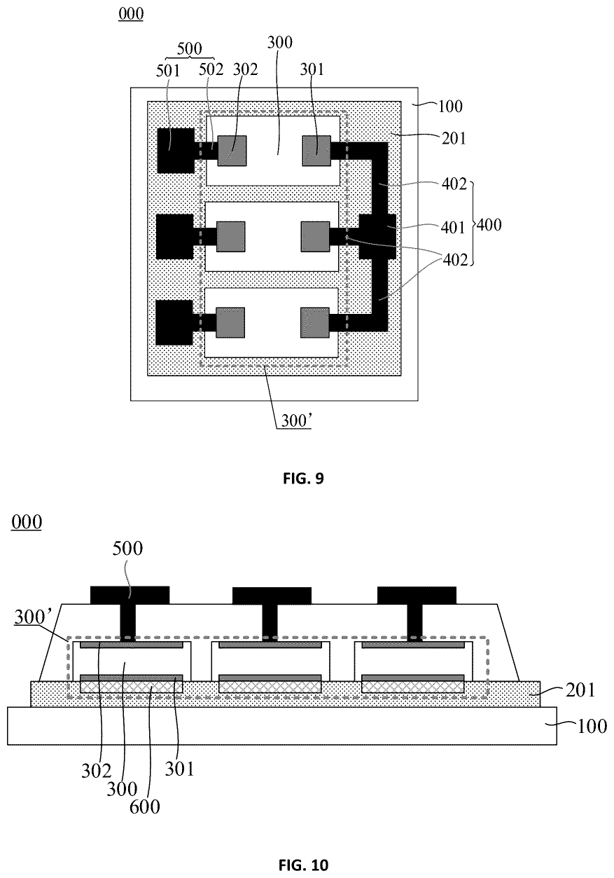

In a first case, as shown in FIGS. 8 and 9, FIG. 8 is a schematic diagram of a film layer structure of a display substrate according to some embodiments of the present disclosure, and FIG. 9 is a top view of the display substrate illustrated in FIG. 8. In a case where the light-emitting diode 300 is a flip-chip type light-emitting diode, i.e., the first electrode 301 and the second electrode 302 of the light-emitting diode 300 are both disposed on the side, away from the substrate 100, of the light-emitting diode 300, the first lap pad 400 includes a first pad body 401 and at least two first connection electrodes 402, and each second lap pad 500 includes a second pad body 501 and a second connection electrode 502.

Here, orthographic projections of the first pad body 401 and the second pad body 501 on the substrate 100 are both outside the orthographic projection of the light-emitting diode 300 on the substrate 100, such that a distance between the first pad body 401 and the second pad body 402 is large.

In the first lap pad 400, the at least two first connection electrodes 402 are in one-to-one correspondence with at least two light-emitting diodes 300 in one corresponding light-emitting diode group 300′. One end of each first connection electrode 402 is lapped to the first electrode 301 of the corresponding light-emitting diode 300, and the other end is electrically connected to the first pad body 402. Here, during the testing stage of the display substrate 000, the first pad body 401 is electrically connected to a probe of the testing equipment; and during the assembly stage of the display substrate 000 and the driving backplane, the first pad body 401 is welded to the driving backplane.

For each second lap pad 500, the second lap pad 500 corresponds to one light-emitting diode 300, and in each second lap pad 500, one end of the second connection electrode 502 is lapped to the second electrode 302 of the corresponding light-emitting diode 300, and the other end is electrically connected to the second pad body 501. Here, during the testing stage of the display substrate 000, the second pad body 501 is electrically connected to a probe of the testing equipment; and during the assembly stage of the display substrate 000 and the driving backplane, the second pad body 501 is soldered to the driving backplane.

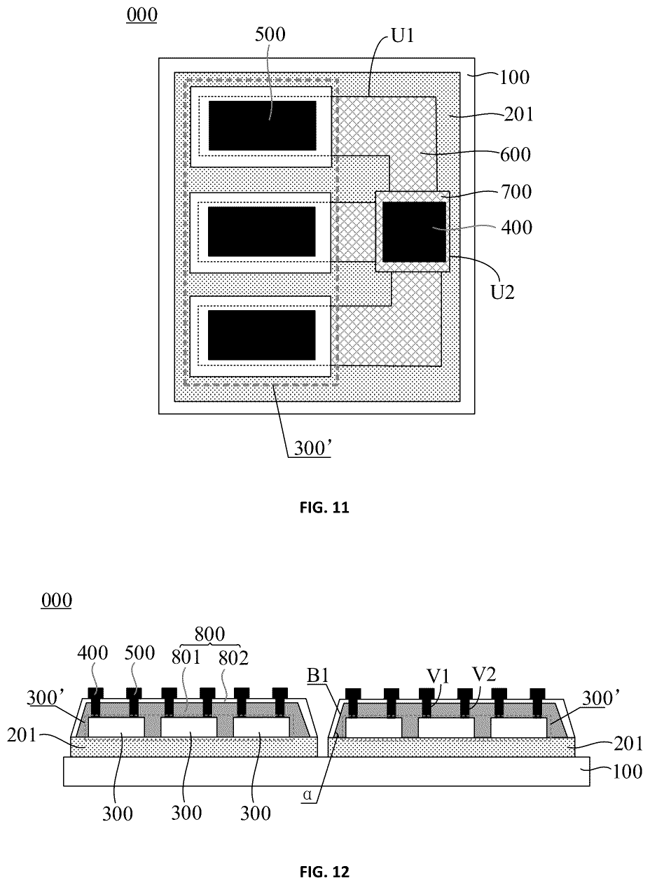

In a second case, as shown in FIGS. 10 and 11, FIG. 10 is a schematic diagram of a film layer structure of another display substrate according to some embodiments of the present disclosure, and FIG. 11 is a top view of the display substrate illustrated in FIG. 10. In a case where the light-emitting diode 300 is a vertical-type light-emitting diode, i.e., the first electrode 301 and the second electrode 302 of the light-emitting diode 300 are disposed on opposite sides of the light-emitting diode 300 in the direction perpendicular to the substrate 100, the display substrate 000 further includes at least two transparent connection electrodes 600, and an auxiliary connection electrode 700 configured to connect the respective transparent connection electrodes 600. Here, the transparent connection electrodes 600 and the auxiliary connection electrode 700 are disposed in the same layer and made of the same material, and the at least two transparent connection electrodes 600 are in one-to-one correspondence with at least two light-emitting diodes 300 in one light-emitting diode group 300′.

Each transparent connection electrode 600 is lapped to the first electrode 301 of the corresponding light-emitting diode 300, and the auxiliary connection electrode 700 is lapped to the first lap pad 400. Here, each transparent connection electrode 600 is electrically connected to the auxiliary connection electrode 700, and each transparent connection electrode 600 is lapped to the first electrode 301 of the corresponding light-emitting diode 300, and the auxiliary connection electrode 700 is lapped to the first lap pad 400. To this end, within one light-emitting diode group 300′, the first electrodes 301 of the respective light-emitting diodes 300 are electrically connected to the same first lap pad 400 by the corresponding transparent connection electrodes 600 and the auxiliary connection electrodes 700.

In the present disclosure, to ensure that each light-emitting diode 300 within one light-emitting diode group 300′ is securely arranged on the corresponding adhesive block 201, the adhesive block 201 corresponding to this light-emitting diode group 300′ has at least two recess U1 therein. The at least two recesses U1 are in one-to-one correspondence with the at least two transparent connection electrodes 600, and each transparent connection electrode 600 is within the corresponding recess U1. In this way, a portion of the first electrode 301 of each light-emitting diode 300 is electrically connected to the corresponding transparent connection electrode 600, and another portion adheres to the corresponding adhesive block 201.

Here, the adhesive block 201 further also has an auxiliary recess U2 therein. The auxiliary recess U2 is configured to communicate the respective recesses U1, and the auxiliary connection electrode 700 is within the auxiliary recess U2. Since the auxiliary recess U2 is in communication with the respective recesses U1, the auxiliary connection electrode 700 distributed within the auxiliary recess U2 is electrically connected to the transparent connection electrode 600 distributed within the recess U1.

In some embodiments of the present disclosure, an orthographic projection of the auxiliary recess U2 on the substrate 100 is outside the orthographic projection of the light-emitting diode 300 on the substrate 100, and the orthographic projection of the first lap pad 400 on the substrate 100 has an overlapping region with the orthographic projection of the auxiliary recess U2 on the substrate 100. In this way, the first lap pad 400 is lapped to the auxiliary connection electrode 700 within the auxiliary recess U2.

In the present disclosure, the orthographic projection of the second lap pad 500 on the substrate 100 is within the orthographic projection of the corresponding light-emitting diode 300 on the substrate 100. The design ideas herein are the same as those of the relevant elements of the above embodiments, which are not repeated herein.

It should be noted that for the second case described above, the above embodiments give the description using the scenario where the first electrodes of the respective light-emitting diodes 300 in one light-emitting diode group 300′ are electrically connected to the same first lap pad 400. In other possible cases, the second electrodes 302 of the respective light-emitting diodes 300 of one light-emitting diode group 300′ are electrically connected to the same second lap pad 500 at the same time, and the first electrodes 301 of the respective light-emitting diodes 300 are electrically connected to different first lap pads 400. In this case, there is no need to provide the auxiliary connection electrode 700 to ensure that there is no electrical connection between the respective transparent connection electrodes 600, and each of the transparent connection electrodes 600 is lapped to one of the first lap pads 400, such that the first electrodes 301 of the respective light-emitting diodes 300 are electrically connected to different first lap pads 400, and the second lap pad 500 is electrically connected to the same first electrodes 301 of the respective light-emitting diodes 300 at the same time. For the content of such lap manner, reference is made to the first case in which the first lap pad 400 is simultaneously lapped with the first electrodes 301 of the respective light-emitting diodes 300 in one light-emitting diode group 300′, which is not repeated herein.

FIG. 12 is a schematic diagram of a film layer structure of yet another display substrate according to some embodiments of the present disclosure. Optionally, as shown in FIG. 12, the display substrate 000 further includes a plurality of insulating protective portions 800. The plurality of insulating protective portions 800 are in one-to-one correspondence with the plurality of adhesive blocks 201 and one-to-one correspondence with the plurality of light-emitting diode groups 300′. Each of the insulating protective portions 800 is configured to cover each of light-emitting diodes 300 in the corresponding light-emitting diode group 300′, and an orthographic projection of the insulating protective portion 800 on the substrate 100 is within the orthographic projection of the corresponding adhesive block 201 on the substrate. Here, each of the light-emitting diodes 300 in the corresponding light-emitting diode group 300′ is protected by the insulating protective portion 800, such that each light-emitting diode 300 is less susceptible to damage by external interference.

In the present disclosure, both the first lap pad 400 and the second lap pad 500 within the display substrate 000 are disposed on a side, away from the substrate 100, of the insulating protective portion 300. That is, after transferring the light-emitting diode 300 to the adhesive block 201, an insulating protective layer is formed on the side, away from the substrate 100, of the light-emitting diode 300, and then a plurality of insulating protective portions 800 are acquired by performing a one-time patterning process on the insulating protective layer. Afterward, a conductive layer formed in a whole layer manner is formed on a side, away from the substrate 100, of the plurality of insulating protective portions 800. The first lap pad 400 and the second lap pad 500 are acquired by performing a one-time pattering process on the conductive layer. Herein, the one-time pattering process includes photoresist coating, exposure, development, and photoresist etching.

It should be noted that in the process of forming the plurality of insulating protective portions 800 by the one-time pattering process, a first via V1 and a second via V2 are also formed in each of the insulating protective portions 800, such that the subsequent first lap pad 400 is lapped to the first electrode 301 of the light-emitting diode 300 by the first via V1, or is lapped to the transparent connection electrode 600; and the subsequent second lap pad 400 is lapped to the first electrode 301 of the light-emitting diode 300 by the first via V1.

In some embodiments of the present disclosure, a boundary of the orthographic projection of the insulating protective portion 800 on the substrate 100 is not overlapped with a boundary of the orthographic projection of the corresponding adhesive block 201 on the substrate 100. That is, the boundary of the orthographic projection of the insulating protective portion 800 on the substrate 100 is at a distance from the boundary of the orthographic projection of the corresponding adhesive block 201 on the substrate 100, such that the orthographic projection of the insulating protective portion 800 on the substrate 100 is ensured to be within the orthographic projection of the corresponding adhesive block 201 on the substrate 100. In this way, in a case where the light-emitting diode 300 corresponding to a certain adhesive block 201 needs to be repaired, after irradiating the laser to the adhesive block 201 to make the adhesion between this adhesive block 201 and the substrate 100 low, the insulating protective portion 800 corresponding to the adhesive block 201 and each of the corresponding light-emitting diodes 300 are all separated from the substrate 100. It should be noted that the boundary of the orthographic projection of the insulating protective portion 800 on the substrate 100 is also coincident with the boundary of the orthographic projection of the corresponding adhesive block 201 on the substrate 100, but in the process of forming the insulating protective portion 800 by the patterning process, there is usually a certain amount of manufacturing error, such that the boundary of the orthographic projection of the insulating protective portion 800 on the substrate 100 is generally spaced apart from the boundary of the orthographic projection of the corresponding adhesive block 201 on the substrate 100.

Optionally, the insulating protective portion 800 in the display substrate 000 includes an organic insulating layer 801 and/or an inorganic insulating layer 802. Here, the organic insulating layer 801 has better flatness and the inorganic insulating layer 802 has better scaling properties.

Exemplarily, in a case where the insulating protective portion 800 includes both the organic insulating layer 801 and the inorganic insulating layer 802, the organic insulating layer 801 is closer to the substrate 100 with respect to the inorganic insulating layer 802. Here, when covering the individual light-emitting diodes 300 within the corresponding light-emitting diode group 300′ by the organic insulating layer 801, a side, away from the substrate 100, of the organic insulating layer 801 has a better flatness. In this way, in a case where the inorganic insulating layer 802 is provided on the organic insulating layer 801, the inorganic insulating layer 802 is not fractured due to excessive segment difference, such that the inorganic insulating layer 802 is capable of better scaling the corresponding light-emitting diode 300, and thus the external water and oxygen are prevented from eroding the light-emitting diode 300 and the service life of the light-emitting diode 300 is not decreased.

In some embodiments of the present disclosure, the organic insulating layer 801 in the insulating protective portion 800 is usually acquired by using exposure and development treatment, and a side surface B1 of the organic insulating layer 801 acquired by exposure and development treatment is usually beveled. Exemplarily, an included angle α between the side surface B1 of the organic insulating layer 801 and a surface, close to the substrate 100, of the organic insulating layer 801 is usually an acute angle. In this case, the inorganic insulating layer 802 is ensured to be properly attached to the side surface B1 of the organic insulating layer 801, and a portion, disposed on the side surface B1 of the organic insulating layer 801, of the inorganic insulating layer 802 is not easily fractured from a portion, disposed on a surface of the organic insulating layer 801 that is away from the substrate 100, of the inorganic insulating layer 802. To this end, an orthographic projection of the organic insulating layer 801 on the substrate 100 is within an orthographic projection of the inorganic insulating layer 802 on the substrate 100, and the inorganic insulating layer 802 is in contact with both the side surface B1 of the organic insulating layer 801 and the surface, away from the substrate 100, of the organic insulating layer 801. In this way, the inorganic insulating layer 802 is capable of sealing both the surface, away from the substrate 100, of the organic insulating layer 801 and the side surface B1 of the organic insulating layer 801. Exemplarily, the inorganic insulating layer 802 and the adhesive block 201 are in direct contact, and here, a region in which the inorganic insulating layer 802 is in contact with the adhesive block 201 is in the shape of a closed ring and surrounds the organic insulating layer 802. In this case, the organic insulating layer 802 is better sealed by the inorganic insulating layer 802, such that the external water and oxygen are prevented from eroding the light-emitting diode 300 through the organic insulating layer 802.

In the present disclosure, in the process of preparing the organic insulating layer 801 in the insulating protective portion 800, it is necessary to ensure that the boundary of the orthographic projection of the organic insulating layer 801 on the substrate 100 is completely within the orthographic projection of the corresponding adhesive block 201 on the substrate 100, and it is necessary to ensure that the distance between the boundary of the orthographic projection of the organic insulating layer 801 on the substrate 100 and the boundary of the orthographic projection of the corresponding adhesive block 201 on the substrate 100 is greater than or equal to a thickness of the inorganic insulating layer 802 to be formed subsequently, such that the boundary of the orthographic projection of the inorganic insulating layer 802 to be formed subsequently is completely within the orthographic projection of the corresponding adhesive block 201 on the substrate 100, and thus the orthographic projection of the insulating protective portion 800 on the substrate 100 is completely within the orthographic projection of the corresponding adhesive block 201 on the substrate 100.

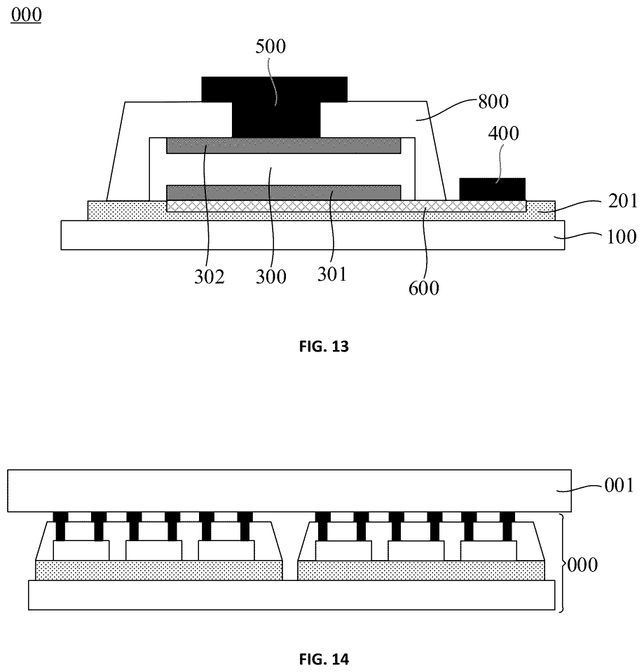

It should be noted that the above embodiments give the description using a scenario where the first conductive pad 400 and the second conductive pad 500 in the display substrate 000 are disposed on the side, away from the substrate, of the insulating protective portion 800 as an example. In other embodiments, as shown in FIG. 13, FIG. 13 is a schematic diagram of a film layer structure of a display substrate according to some embodiments of the present disclosure. In a case where the light-emitting diode 300 is a vertical-type light-emitting diode 300, the second lap pad 500 is disposed on the side, away from the substrate 100, of the insulating protective portion 800, and the first lap pad 400 is disposed on the side, away from the substrate 100, of the adhesive block 201, and it needs to be ensured that the first lap pad 400 is not overlapped with the orthographic projection of the insulating protective portion 800 on the substrate 100.

Exemplarily, in a case where the light-emitting diode 300 is a vertical-type light-emitting diode 300, there are transparent connection electrodes 600 distributed between the light-emitting diode 300 and the adhesive block 201. One portion of the transparent connection electrodes 600 is lapped to the first electrode 301 of the light-emitting diode 300, the other portion is required to extend outside the insulating protective portion 800, and the portion, extending outside the insulating protective portion 800, of the transparent connection electrodes 600 is lapped to the first lap pad 400, such that the first lap pad 400 is lapped to the first electrode 301 of the light-emitting diode 300 by the transparent connection electrode 600.

In summary, some embodiments of the present disclosure provide a display substrate, including: the substrate, the adhesive layer, and the plurality of light-emitting diodes. The adhesive layer includes the plurality of adhesive blocks corresponding to the plurality of light-emitting diodes. The adhesive layer is an adhesive layer whose adhesion decreases under the irradiation by a laser. In the case where each light-emitting diode in the display substrate is adhered to the substrate by the corresponding adhesive block, if the light emitted from a certain light-emitting diode is found to be defective in the testing process of the light-emitting diodes, the laser light is irradiated to the adhesive block corresponding to this light-emitting diode, such that the adhesion between the adhesive block and the substrate is reduced, and thus the adhesive block is separated from the substrate. In this way, the defective light-emitting diode is detached from the substrate, such that a new adhesive block is subsequently provided and a new light-emitting diode is adhered to the adhesive block. To this end, by providing the adhesive layer whose adhesive property is reduced under the laser irradiation on the substrate and adhering the light-emitting diode to the adhesive layer, the defective light-emitting diode in the display substrate can be repaired, such that each of the light-emitting diodes in the display substrate is ensured to emit light normally, and thus the display effect of the display panel is ensured to be good after the display substrate is subsequently assembled into the display panel.

FIG. 14 is a schematic diagram of a film layer structure of a display panel according to some embodiments of the present disclosure. Referring to FIG. 14, the display panel includes a display substrate 000 and a driving backplane 001. Here, the display substrate 000 is the display substrate in the above embodiments.

In the present disclosure, the driving backplane 001 in the display panel is disposed on a side, away from the substrate 100, of the plurality of light-emitting diodes 300 in the display substrate 000, and the driving backplane 001 is electrically connected to the respective light-emitting diodes 300.

Exemplarily, each of the light-emitting diodes 300 in the display substrate 000 is electrically connected to the driving backplane 001 by welding. Here, the driving backplane 000 includes a pixel driving circuit electrically connected to the light-emitting diodes 300, and the corresponding light-emitting diode 300 is driven to emit light by the pixel driving circuit, such that the display panel displays corresponding images.

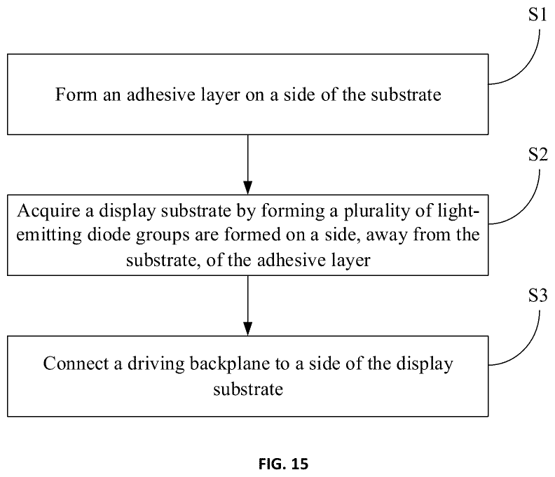

Some embodiments of the present disclosure further provide a method for preparing a display panel. The method for preparing the display panel is used to prepare the display panel as described above. FIG. 15 is a flowchart of a method for preparing a display panel according to some embodiments of the present disclosure. Referring to FIG. 15, the method includes the following steps.

In step S1, an adhesive layer is formed on a side of the substrate, wherein the adhesive layer includes a plurality of adhesive blocks arranged in an array, and the adhesive layer is an adhesive layer whose adhesion decreases under the irradiation by a laser.

In step S2, a display substrate is acquired by forming a plurality of light-emitting diode groups are formed on a side, away from the substrate, of the adhesive layer, wherein each of the light-emitting diode groups includes at least one light-emitting diode, and the plurality of light-emitting diode groups are in one-to-one correspondence with the plurality of adhesive blocks.

In Step S3, a driving backplane is connected to a side of the display substrate, wherein the driving backplane is disposed on a side, away from the substrate of the plurality of light-emitting diodes in the display substrate, and the driving backplane is electrically connected to the respective light-emitting diodes.

It should be noted that the preparation processes of step S11 and step S13 described above refer to the corresponding contents in the above structural embodiments of the display substrate or the display panel, which are not limited herein.

Optionally, prior to connecting the driving backplane to the display substrate, the display substrate needs to be tested and any defective light-emitting diode in the display substrate needs to be repaired, such that each light-emitting diode within the display substrate is ensured to emit light normally.

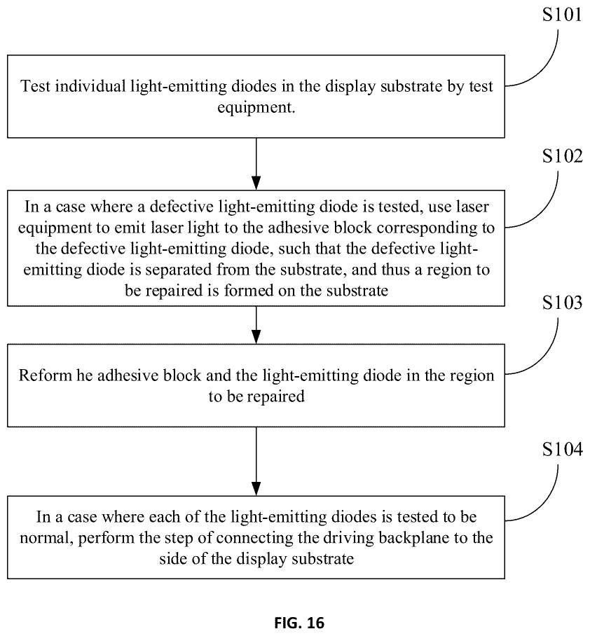

Exemplarily, reference is made to FIG. 16, which is a flowchart of a method for testing a display substrate according to some embodiments of the present disclosure. The method includes the following steps.

In step S101, individual light-emitting diodes in the display substrate are tested by test equipment.

In some embodiments of the present disclosure, after forming the display substrate, the individual light-emitting diodes in the display substrate are tested by the test equipment. Exemplarily, a first lap pad and a second lap pad are disposed on a side, away from a substrate, of the light-emitting diode in the display substrate, and the first lap pad and the second lap pad are respectively electrically connected to a first electrode and a second electrode of the light-emitting diode. Therefore, after two probes in the testing equipment respectively abut the first conductive pad and the second conductive pad to which the light-emitting diode is connected, the test equipment is electrically connected to this light-emitting diode, and thus after the test equipment transmits a test signal to this light-emitting diode, the test equipment controls the light-emitting diode to light up.

Here, in a case where the light-emitting diode is lit normally, and the luminance of the light emitted from the light-emitting diode is within a specified luminance range, the light-emitting diode belongs to a normal light-emitting diode; and in a case where the light-emitting diode cannot be lit, or the light-emitting diode 300 is lit, but the luminance of the light emitted from the light-emitting diode is low, the light-emitting diode belongs to a defective light-emitting diode, and the following step S102 needs to be performed.

In step S102, in a case where a defective light-emitting diode is tested, laser equipment is used to emit laser light to the adhesive block corresponding to the defective light-emitting diode, such that the defective light-emitting diode is separated from the substrate, and thus a region to be repaired is formed on the substrate.

In some embodiments of the present disclosure, ion the case where a defective light-emitting diode is tested, the laser equipment is used to emit laser light to the adhesive block corresponding to the defective light-emitting diode, such that the adhesion between this adhesive block and the substrate is low, and thus this adhesive block is separated from the substrate, which ensures that the defective light-emitting diode is detached from the substrate. Here, after this adhesive block is detached from the substrate, the region to be repaired is formed on the substrate, which is a region previously used to adhere the defective light-emitting diode.

In step S103, the adhesive block and the light-emitting diode are re-formed in the region to be repaired.

In some embodiments of the present disclosure, after separating the defective light-emitting diode from the substrate, the adhesive block is re-formed within the to-be-repaired region of the substrate and the light-emitting diode is re-formed on the adhesive block by a transfer process. Afterward, this re-transferred new light-emitting diode needs to be tested. That is, the above step 101 is performed on this re-transferred new light-emitting diode.

In step S104, in a case where each of the light-emitting diodes is tested to be normal, the step of connecting the driving backplane to the side of the display substrate is performed.

In some embodiments of the present disclosure, in the case where the individual light-emitting diodes in the display substrate are tested to be normal, a display panel is acquired by connecting the driving backplane to the side of the display substrate. In this way, the individual light-emitting diodes within the display panel are capable of emitting light normally, such that the display effect of the display panel is ensured to be good.

Some embodiments of the present disclosure further provide an electronic device. The electronic device may be a mobile phone, a tablet computer, a television, a monitor, a laptop computer, a digital photo frame, a navigator, or any other product or component having a display function. The electronic device includes a power supply component, and a display panel electrically connected to the power supply component. The display panel is the display panel as described above. For example, the display panel is the display panel illustrated in FIG. 14.

It should be noted that in the accompanying drawings, the sizes of layers and regions may be exaggerated for clearer illustration. It should be understood that where an element or layer is referred to as being “on” another element or layer, the element or layer may be directly on another element, or intervening layers therebetween may be present. In addition, it should be understood that where an element or layer is referred to as being “under” another element or layer, the element or layer may be directly under the other element, or there may be more than one intervening layer or element. In addition, it may be further understood that in the case that a layer or element is referred to as being “between” two layers or two elements, the layer may be the only layer between the two layers or two elements, or more than one intervening layer or element may further be present. Like reference numerals indicate like elements throughout.

In the present disclosure, the terms “first” and “second” are only used for descriptive purposes, and cannot be understood as indicating or implying relative importance. The term “a plurality of” refers to two or more, unless expressly defined otherwise.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. A display substrate, comprising:
a substrate;
an adhesive layer disposed on a side of the substrate, wherein the adhesive layer comprises a plurality of adhesive blocks arranged in an array; and
a plurality of light-emitting diode groups disposed on a side, away from the substrate, of the adhesive layer, wherein each of the plurality of light-emitting diode groups comprises at least one light-emitting diode, and the plurality of light-emitting diode groups are in one-to-one correspondence with the plurality of adhesive blocks;
wherein the adhesive layer is an adhesive layer whose adhesion decreases under irradiation by a laser.

2. The display substrate according to claim 1, wherein an orthographic projection of a light-emitting region of the light-emitting diode in the light-emitting diode group on the substrate is within an orthographic projection of a corresponding adhesive block of the plurality of adhesive blocks on the substrate.

3. The display substrate according to claim 1, wherein the light-emitting diode has a first electrode and a second electrode, and the display substrate further comprises a first conductive pad electrically connected to the first electrode and a second conductive pad electrically connected to the second electrode, at least one of the first conductive pad and the second conductive pad being disposed on a side, away from the substrate, of the light-emitting diode.

4. The display substrate according to claim 3, wherein the first electrode and the second electrode of the light-emitting diode are both disposed on the side, away from the substrate, of the light-emitting diode, and a side, close to the substrate, of the light-emitting diode is adhered to a corresponding adhesive block of the plurality of adhesive blocks.

5. The display substrate according to claim 3, wherein the first electrode and the second electrode of the light-emitting diode are disposed on opposite sides of the light-emitting diode in a direction perpendicular to the substrate, and the first electrode is closer to the substrate relative to the second electrode; and
the display substrate further comprises a transparent connection electrode disposed between the light-emitting diode and the adhesive block, wherein the transparent connection electrode is electrically connected to the first electrode of the light-emitting diode and the first conductive pad.

6. The display substrate according to claim 5, wherein a recess is formed in a side, away from the substrate, of the adhesive block, wherein the transparent connection electrode is disposed within the recess, and a thickness of the transparent connection electrode is greater than or equal to a depth of the recess; and a portion of the first electrode of the light-emitting diode is lapped to the transparent connection electrode, and the other portion of the first electrode of the light-emitting diode is affixed with the adhesive block.

7. The display substrate according to claim 6, wherein an orthographic projection of the recess on the substrate has at least one first side edge and at least one second side edge, wherein at least a portion of the first side edge is disposed within an orthographic projection of the light-emitting diode on the substrate, and the second side edge is disposed outside the orthographic projection of the light-emitting diode on the substrate.

8. The display substrate according to claim 7, wherein the orthographic projection of the light-emitting diode on the substrate has a third side edge adjacent to the first side edge, wherein a horizontal distance between the third side edge and the adjacent first side edge is greater than or equal to 2.5 microns.

9. The display substrate according to claim 3, wherein the light-emitting diode group comprises at least two light-emitting diodes, wherein an orthographic projection of the light-emitting region of each of the light-emitting diodes in the light-emitting diode group on the substrate is within an orthographic projection of a corresponding adhesive block of the plurality of adhesive blocks on the substrate;
wherein in one of the light-emitting diode groups, the first electrodes of the respective light-emitting diodes are electrically connected to a same first lap pad, and the second electrodes of the respective light-emitting diodes are electrically connected to different second lap pads.

10. The display substrate according to claim 9, wherein the first electrode and the second electrode of the light-emitting diode are both disposed on the side, away from the substrate, of the light-emitting diode, the first lap pad comprises a first pad body and at least two first connection electrodes, and each of the second lap pads comprises a second pad body and a second connection electrode; wherein
an orthographic projection of the first pad body on the substrate and an orthographic projection of the second pad body on the substrate are both outside an orthographic projection of the light-emitting diode on the substrate;
in the first lap pad, the at least two first connection electrodes are in one-to-one correspondence with the at least two light-emitting diodes, one end of the first connection electrode is lapped to the first electrode of a corresponding light-emitting diode of the two light-emitting diodes, and the other end of the first connection electrode is electrically connected to the first pad body; and
in each of the second lap pads, one end of the second connection electrode is lapped to the second electrode of a corresponding light-emitting diode of the two light-emitting diodes, and the other end of the second connection electrode is electrically connected to the second pad body.

11. The display substrate according to claim 9, wherein the first electrode and the second electrode of the light-emitting diode are disposed on opposite sides of the light-emitting diode in a direction perpendicular to the substrate, and the display substrate further comprises at least two transparent connection electrodes in one-to-one correspondence with the at least two light-emitting diodes, and an auxiliary connection electrode configured to connect each of the transparent connection electrodes;
wherein each of the transparent connection electrodes is lapped to the first electrode of a corresponding light-emitting diode of the two light-emitting diodes, and the auxiliary connection electrode is lapped to the first lap pad.

12. The display substrate according to claim 11, wherein at least two recesses in one-to-one correspondence with the at least two transparent connection electrodes, and an auxiliary recess configured to communicate with each of the at least two recesses are arranged in the adhesive block corresponding to one of the light-emitting diode groups, wherein each of the transparent connection electrodes is disposed in a corresponding recess, and the auxiliary connection electrode is disposed in the auxiliary recess.

13. The display substrate according to claim 12, wherein
an orthographic projection of the auxiliary recess on the substrate is outside an orthographic projection of the light-emitting diode on the substrate, and an overlapping region is present between an orthographic projection of the first lap pad on the substrate and the orthographic projection of the auxiliary recess on the substrate; and
an orthographic projection of the second lap pad on the substrate is within the orthographic projection of the light-emitting diode on the substrate.

14. The display substrate according to claim 1, further comprising: a plurality of insulating protective portions, wherein the plurality of insulating protective portions are in one-to-one correspondence with the plurality of adhesive blocks and in one-to-one correspondence with the plurality of light-emitting diode groups;
wherein each of the plurality of insulating protective portions is configured to cover the light-emitting diode in a corresponding light-emitting diode group of the plurality of light-emitting diode groups, and an orthographic projection of the insulating protective portions on the substrate is within an orthographic projection of a corresponding adhesive block of the plurality of adhesive blocks on the substrate.

15. The display substrate according to claim 14, further comprising: a first lap pad and a second lap pad that are configured to be electrically connected to the light-emitting diode; wherein
the first lap pad and the second lap pad are both disposed on a side, away from the substrate, of the insulating protective portion; or
the second lap pad is disposed on the side, away from the substrate, of the insulating protective portion, and the first lap pad is disposed on a side, away from the substrate, of the adhesive block, and an orthographic projection of the first lap pad on the substrate is not coincident with the orthographic projection of the insulating protective portion on the substrate.

16. The display substrate according to claim 14, wherein the insulating protective portion comprises an organic insulating layer and/or an inorganic insulating layer;
wherein the organic insulating layer covers each of the light-emitting diodes in a corresponding group of the light-emitting diode groups, and an angle between a side surface of the organic insulating layer and a side surface, close to the substrate, of the organic insulating layer is an acute angle.

17. The display substrate according to claim 16, wherein the insulating protective portion comprises both the organic insulating layer and the inorganic insulating layer, the organic insulating layer being closer to the substrate relative to the inorganic insulating layer;
wherein the inorganic insulating layer is in contact with both the side surface of the organic insulating layer and a surface, away from the substrate, of the organic insulating layer.

18. The display substrate according to claim 17, wherein an orthographic projection of the organic insulating layer on the substrate is within an orthographic projection of the inorganic insulating layer on the substrate;
wherein the inorganic insulating layer is in direct contact with the adhesive block, and a region where the inorganic insulating layer is in contact with the adhesive block is in a closed ring shape and surrounds the organic insulating layer.

19. A display panel, comprising: a display substrate and a driving backplane, the display substrate comprises:
a substrate;
an adhesive layer disposed on a side of the substrate, wherein the adhesive layer comprises a plurality of adhesive blocks arranged in an array; and
a plurality of light-emitting diode groups disposed on a side, away from the substrate, of the adhesive layer, wherein each of the plurality of light-emitting diode groups comprises at least one light-emitting diode, and the plurality of light-emitting diode groups are in one-to-one correspondence with the plurality of adhesive blocks;
wherein the adhesive layer is an adhesive layer whose adhesion decreases under irradiation by a laser; and
wherein the driving backplane is disposed on a side, away from the substrate, of the plurality of light-emitting diode groups in the display substrate, and the driving backplane is electrically connected to each of the light-emitting diodes.

20. A method for preparing a display panel, comprising:
forming an adhesive layer on a side of a substrate, wherein the adhesive layer comprises a plurality of adhesive blocks arranged in an array, and the adhesive layer is an adhesive layer whose adhesion decreases under irradiation of a laser;
acquiring a display substrate by forming a plurality of light-emitting diode groups on a side, away from the substrate, of the adhesive layer, wherein each of the light-emitting diode groups comprises at least one light-emitting diode, and the plurality of light-emitting diode groups are in one-to-one correspondence with the plurality of adhesive blocks; and
connecting a driving backplane to a side of the display substrate, wherein the driving backplane is disposed on a side, away from the substrate, of the plurality of light-emitting diodes in the display substrate, and the driving backplane is electrically connected to each of the light-emitting diodes.
